(19) United States
(12) Patent Application Publication
(10) Pub. No.: US 2019/0033930 A1
(43) Pub. Date: Jan. 31, 2019

(54) COOLING DEVICE FOR USE IN HEAT DISSIPATION ASSOCIATED WITH ELECTRONIC COMPONENTS

(71) Applicant: Optimus Water Cooling Corporation, Addison, IL (US)

(72) Inventor: Christopher Rupprecht, Wayne, IL (US)

(21) Appl. No.: 16/043,459

(22) Filed: Jul. 24, 2018

Related U.S. Application Data
(60) Provisional application No. 62/537,048, filed on Jul. 26, 2017.

(51) Int. Cl. G06F 1/20; H01L 23/473; H05K 7/20

(52) U.S. Cl. CPC G06F 1/20; G06F 2200/201; H05K 7/20263; H01L 23/473

(57) ABSTRACT

The present disclosure relates to a device for effectively dissipating heat from computer components, including those components which tend to generate significant amounts of heat, including CPUs and GPUs. The present disclosure relates to an improved cooling device, specifically an improved water block incorporating plurality of fins, having a unique, alternating grouping arrangement, which provide a concentrated cooling surface and better cooling performance when used in a system for dissipating heat from computer and electronic components.

### TECHNICAL FIELD

The present invention relates to a device, systems and methods for cooling electronic components. More specifically, a cooling device in the form of an improved water block heat exchanger for effectively dissipating heat from computer components, is provided. Additionally, systems and methods for dissipating heat from computer components incorporating an improved cooling device, are also provided.

### BACKGROUND

It is, of course, generally known that electronic components, and those components integral to operating computer systems, including personal computer systems, generate a considerable amount of heat. For example, in a typical personal computer, the CPU (Central Processing Unit) chip, GPU (Graphic Processing Unit), PPU (Physics Processing Unit) are often the components that generate the greatest amount of heat. In order to maintain proper operation of computer components, including for and during extended use, enhanced performance and to prevent damage, heat must be efficiently and effectively released from the components.

Heat sinks and water blocks are typically used as a solution for tackling the heat issues relating to computer components. Heat sinks and water blocks are typically placed directly on the component requiring cooling, such as the CPU. A heat sink is a passive heat exchanger that transfers the heat generated by a component to a fluid medium, often air or a liquid coolant, where it is dissipated away from the component, thereby allowing regulation of the component's temperature at optimal levels. A heat sink is designed to maximize its surface area in contact with the cooling medium surrounding it, such as the air. Thus, a heat sink generally incorporates a plurality of fins, the design of which can increase the surface area for conducting heat away from the CPU unit the heat sink is placed on. Fins generally extend upward from the base of the heat sink, and can be any suitable shape including cylindrical and square, as well as, have a variety of arrangements from straight to flared.

Water blocks are the water-cooled equivalent of a heat sink. Water blocks act as a radiator, where the water circulating within the channels of the block dissipates the heat generated by the component. A water block is better at dissipating heat than an air-cooled heatsink due to water's higher specific heat capacity and thermal conductivity. A fan may also be incorporated into the cooling system to further expel the heat created from the specific components. A radiator-style cooling component is typically more efficient than a standard CPU or GPU heatsink/air cooler at removing heat because it has a much larger surface area.

One problem with cooling CPUs and other components is that the heat load emitted is very concentrated. Thus, in order to obtain effective cooling, there must be an increase in the cooling surface area. However, in today's scaled-down electronics, having additional surface area to accommodate an effective cooling device is not always practical, efficient or even possible.

A need, therefore, exists for an improved device, system and method for effectively dissipating heat from electronic components, particularly computer components. Specifically, a need exists for an improved device, systems and methods that allow effective and efficient cooling of CPU components utilizing an increase in surface area yet able to be placed in a relatively small space.

Moreover, a need exists for an improved device, system and method for effectively cooling electronic components wherein the cooling device provides a greater surface area for more efficient heat dissipation.

Additionally, a need exists for an improved cooling device that can be incorporated into a smaller space often found in today's scaled-down electronic devices, and yet provide more effective heat dissipation and cooling advantages over device currently in use.

### SUMMARY

The present disclosure relates to a device for effectively dissipating heat from computer components, including those components which tend to generate significant amounts of heat, including CPUs and GPUs. The present disclosure relates to an improved cooling device, specifically an improved cooling device or water block incorporating plurality of fins, having a unique arrangement. The unique arrangement of the cooling fins of the present device provide a concentrated cooling surface and better cooling performance when used in a system for dissipating heat from computer components.

To this end, in an embodiment of the present disclosure, a device for dissipating heat generated by electronic components, particularly computer components, is provided. The present device comprises a base, a plurality of fins disposed on a surface of the base, and a plurality of channels disposed between the fins.

In another embodiment of the present disclosure, a device for dissipating heat generated by computer components, is provided. The comprises a base, a plurality of fins disposed on a surface of the base, wherein the plurality of fins are arranged in groupings on the surface of the base the plurality of fins, including a first group of fins having a first size and a second group of fins having a second size, and a plurality of channels disposed between the first and second group of fins.

In another embodiment of the present disclosure, a system for dissipating heat from computer components is provided. The system includes at least one water block heat exchanger comprising a base, a plurality of fins positioned in sequential groupings or array of fins of varying sizes on a surface of the base; and, a plurality of channels disposed between the sequence of fins, a coolant reservoir having a coolant pump, and a plurality of conduit to connect the various components of the system and to accommodate the flow of coolant between the pump and reservoir to the water block. The system may also include a fan.

It is, therefore, an advantage and objective of the present disclosure to provide an improved cooling device in the form of a water block heat exchanger for effectively dissipating heat from computer components.

Yet another an advantage and objective of the present disclosure to provide an improved water block heat exchanger having a unique arrangement of cooling fins, which provide improved heat dissipation performance for computer components.

It is further an advantage and objective of the present disclosure to provide an improved water block heat exchanger having a unique arrangement of cooling fins, which provide a larger surface area for effectively cooling components in smaller spaces.

It is yet another advantage and objective of the present disclosure to provide an improved water block heat exchanger having a plurality of cooling fins of various sizes in a unique arrangement, which provide a larger surface area for effective cooling.

Another advantage and objective of the present disclosure is to provide an improved water block heat exchanger having a plurality of cooling fins that are structurally supported to avoid becoming fragile during use and manufacturing.

Additional features and advantages of the present disclosure are described in, and will be apparent from, the detailed description of the presently preferred embodiments and from the drawings.

### BRIEF DESCRIPTION OF THE DRAWINGS

The drawing figures depict one or more implementations in accord with the present concepts, by way of example only, not by way of limitations. In the figures, like reference numerals refer to the same or similar elements.

FIG. 1 illustrates a perspective view of a bottom plate of a cooling device according to the present disclosure;

FIG. 2 illustrates a close-up of the groupings of fins of the cooling device according to the present disclosure; and,

FIG. 3 illustrates an embodiment of the groupings of fins of the cooling device according to the present disclosure.

### DETAILED DESCRIPTION

The present disclosure relates to a device for cooling computer components, including those components which tend to generate significant amounts of heat, including CPUs and GPUs. Specifically, the present disclosure is directed to an improved cooling device or heat dissipation device, including an improved water block heat exchanger for use in a liquid cooling system for computer components, wherein the present device includes a unique array of cooling fins.

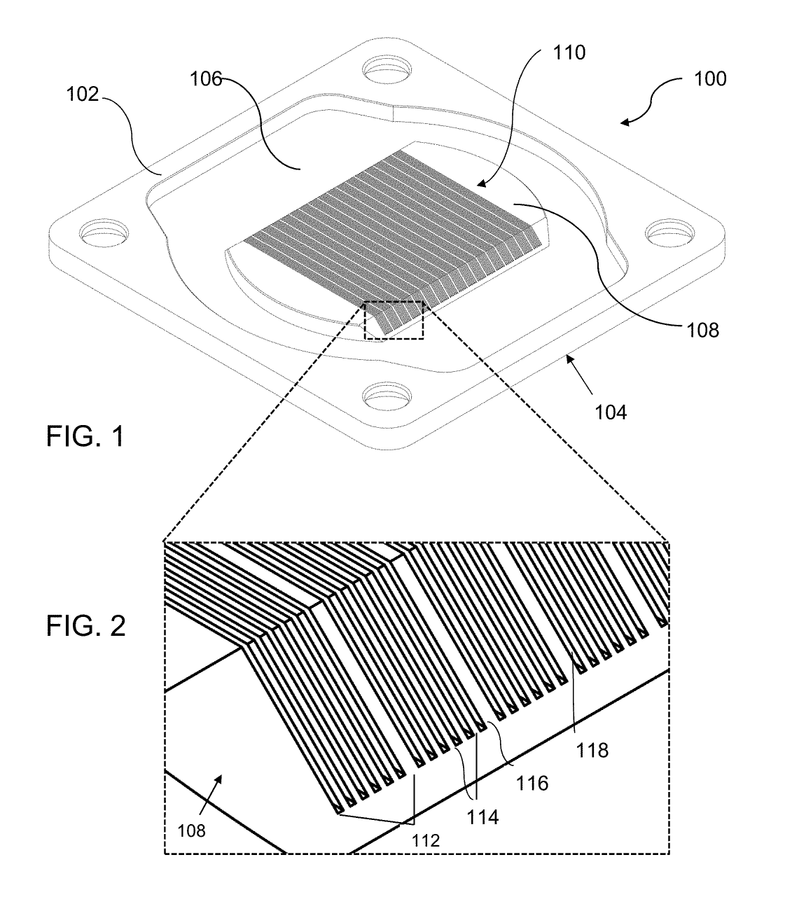

Now referring to the figures, wherein like numerals refer to like parts, FIG. 1 illustrates a perspective view of a cooling device 100 useful in a heat dissipating system and method for cooling computer components (not shown). The cooling device 100, which may also be referred to as a water block heat exchanger, is for use with computer components, such as a CPU or GPU, which generally generate significant amounts of heat while in use. As is generally understood, in a typical water cooling system for electronic components, the water block heat exchanger is typically connected through a plurality of lines or conduit to a fluid reservoir containing coolant for circulation through the system and water block. A coolant pump is used for circulating the coolant from the fluid reservoir through the conduit and to the water block for dissipating heat from the CPU.

In order to effectively cool a particular component, the cooling device 100 or water block heat exchanger is sized for placement in direct contact with the target computer component, such as a CPU or GPU (not shown). The cooling device 100 can be surface mounted to the CPU, using any known suitable attachment, including either mechanical fasteners or adhesive. Optimum heat transfer from the CPU through the cooling device 100 is achieved by ensuring a good contact between the water block and the CPU or other component to be cooled.

Referring to FIGS. 1 and 2, an embodiment of an improved cooling device 100 for use with electronic components, and computer components, such as CPU and/or GPU, is provided. FIG. 1 illustrates the bottom plate of an improved cooling device 100 also referred to as a water block heat exchanger, or water block, according to the present disclosure. As is generally know, the cooling device 100 comprises at least two main parts—a base 102 having a bottom plate 104, as shown in FIG. 1, which is the area of the cooling device that makes contact with the component being cooled, and a top (not shown) or top plate. As is known, the top plate is secured over the base 102 using known fasteners, which ensures the coolant liquid is contained within the body of the cooling device. The shape and size of the top plate may vary for a particular cooling device.

The base 102 further includes a depression 106 within the base for receiving a cooling liquid, and a raised platform 108 within the center of the depression on which the plurality of fins 110 are arranged in a compact structure 112. The compact fin structure 112 includes a specific array or groups of small fins 114 to large fins 116, with channels 118 there between. The top plate (not shown) may further include a plurality of suitable connections (not shown) for attachment of conduit (not shown), which allows the coolant to enter the body 102 of the present cooling device and the enclosed depression 106 for circulation within the body and the channels 118 between the plurality of fins 110.

The base 102 and bottom plate 104 of the present cooling device 100 are usually manufactured from metals with high thermal conductivity such as aluminum or copper. The present cooling device 100 has a generally square shape, having similar size dimensions to the appropriate CPU or other component on which it rests. However, it should be understood that the present cooling device 100 can be any shape suitable for a particular purpose or component or customized for a particular use or component.

Referring to FIG. 2, there is shown a close-up view of raised platform 108 of the base 102 of the present cooling device 100, as well as the plurality of fins 110. The raised platform 108 includes a plurality of fins 110, which are arranged in a groupings of compact structures 112 along a surface 108a of the platform. Between each individual fin 114, 116 is a channel 118, which permits the flow of water or other liquid coolant through the present water block device 100. Typically, the thinner or smaller the size of the fins, particularly the first set of fins 114, and channels 118, the more fins are able to fit into a given area, thereby providing a higher concentration of surface area, and a better heat removal rate. Therefore, water block devices 100 with multiple groups of thinner fins and channels, such as those of the present disclosure, tend to have better heat dissipation performance. However, if fins are too thin, they become fragile and are likely to bend over or be destroyed during the manufacturing process. Therefore, the present device 100 utilizes a unique grouping of a first set of small fins 114 separated and supported by a second set of larger support fins 116.

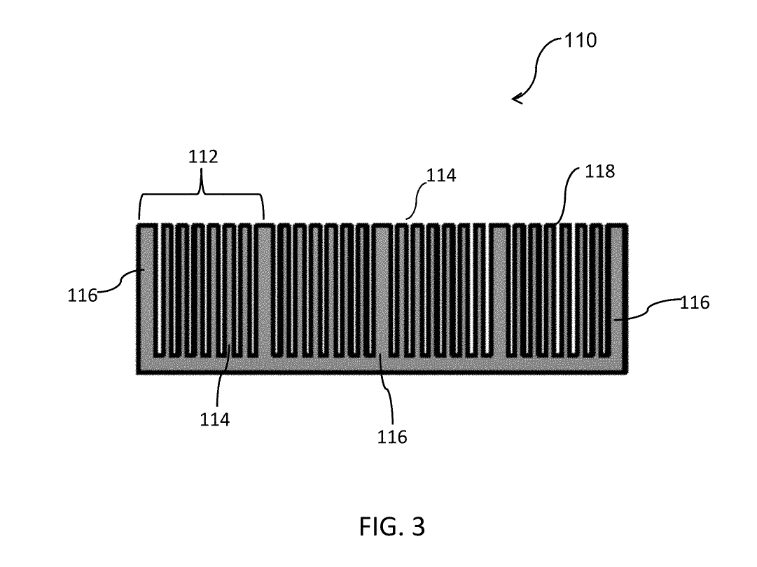

In a present embodiment, the plurality of fins 110 comprise an array or groupings of compact structures 112 comprised of a plurality individual fins of at least two different sizes, arranged in a sequential, alternating manner. As shown in FIGS. 2 and 3, the plurality of the fins 110 defining the compact structure 112, include a first set of smaller, thinner fins 114, supported by a second set of at least one single, larger support fin 116. These groupings of fin structures 112 are arranged in an alternating order, where the smaller fins 114 may include comprised of any number of fins followed by a support fin 116.

For example, as shown in the embodiment in FIG. 3, there is a first set of 6 smaller fins 114, followed by a single support fin 116, followed by another set of 6 smaller fins, followed by another single support fin 116, and so on. However, it should be understood that any number of smaller fins 114 may be used in the first set of a particular arrangement, including up to 12 or more smaller fins 114, followed by a single support fin 116, which is then followed by another group of 6 to 12 smaller fins and so on. Ideally, the more fins that can be placed in a particular group results in a device with great capacity for heat dissipation. The structural integrity of the multiple smaller fins 114 is created by the placement of the larger support fin 116 between the groups of small fins. It should be understood that although a particular embodiment is illustrated, the arrangement or groupings of the compact structure 112 of fins can include any suitable number and combination of smaller fins 114 to support fins 116.

The smaller fins 114 making up the first group or set of fins useful in the present cooling device 100 can include width dimensions ranging from 0.004 inches thick to 0.008 inches thick, with 0.005 inches being a preferred thickness. The support fins 116 making up the second group or set can include a thickness ranging from 0.01 inches to 0.03 inches thick, depending on the length of the fins, which can range between about 1.0 inches to about 1.5 inches. Longer, smaller fins 114 need thicker, support fins 116 to prevent bending over or being damaged. The use of the two difference size fins 114, 116 and the grouping arrangements of the fins in the present water block/cooling device 100 is advantageous because multiple thin fins provide significant amounts of surface area for concentrated, effective heat dissipation, while alternatively being useful for smaller components because of the compact nature of the overall groupings of the fins. The addition of the larger support fin 116 provides improved structural support to the smaller fins 114. The structural support provided by the support fin 116 overcomes the issues relating to potential fragility of thinner fins 114, such as preventing the thinner fins from bending over or being damaged or destroyed.

As shown in FIG. 2, channels 118 are present between each of the small fins 112 and support fins 116. The channels 118 are typically consistent in width, ranging from 0.004 inches to 0.006 inches. The channels 118 are configured to receive a cooling liquid, such as water, which flows within the depression 106 of the base 102 and through the channels between the fins 112, 114, effectively assisting in the heat dissipation function of the present cooling device 100.

The present cooling device 100 can be constructed from a single piece of thermal conductive material, such as copper or aluminum. Specifically, the base 102, fin groupings 112 and channels 118 are precisely machined as one piece using a CNC (computer numeric control) machine using known processes. A top plate (not shown) is attached using known attachment methods and fasteners.

The present cooling device 100 is useful in a system for dissipating heat from a computer components. The system for dissipating heat includes well-known components including fans, and heat dissipating devices, such as water block device. The present cooling device 100, provides a unique heat-dissipating element to a system for cooling the heat-generating components of a computer system, particularly because of the device's unique fin array utilizing a combination of smaller and larger fins. Additionally, although ranges are provided for fin and channel width and length, it should be understood that any combination of fin and channel sizes may be used depending on specific requirements.

It should be noted that various changes and modifications to the presently preferred embodiments described herein will be apparent to those skilled in the art. Such changes and modifications may be made without departing from the spirit and scope of the present invention and without diminishing its attendant advantages. Further, references throughout the specification to “the invention” are nonlimiting, and it should be noted that claim limitations presented herein are not meant to describe the invention as a whole. Moreover, the invention illustratively disclosed herein suitably may be practiced in the absence of any element which is not specifically disclosed herein.

I claim:

1. A device for dissipating heat generated by electronic components, the device comprising:
a base;
a plurality of fins positioned on a surface of the base; and,
a plurality of channels disposed between the fins.

2. The device of claim 1, wherein the device further includes a cover.

3. The device of claim 1, wherein the plurality of fins are arranged in a block configuration on the surface of the base.

4. The device of claim 3, wherein the plurality of fins are arranged in groupings on the surface of the base.

5. The device of claim 4, wherein the groupings of fins include alternating groupings based on sizes of fins on the surface of the base.

6. The device of claim 5, wherein the alternating groupings include a first set comprising a plurality of the same size fins together, followed by a second set comprising at least one fin of a size larger than the first set of the fins.

7. The device of claim 6, wherein the alternating groupings include the first set comprising a plurality of fins followed by the second set of a single fin as a support fin.

8. The device of claim 6, wherein each fin of the first set of fins has a width between about 0.004 inches to about 0.008 inches.

9. The device of claim 6, wherein the fin of the second set of fins has a width in the range of between about 0.01 inches to about 0.03 inches thick.

10. The device of claim 1, wherein the plurality of channels include a channel between each fin of the first set of fins and the second set of fins, and wherein the channels are included in the alternating groups on the surface of the base.

11. The device of claim 10, wherein the channels have a uniform width between individual fins.

12. The device of claim 11, wherein the channels range in width between the fins of about 0.004 inches to about 0.006 inches.

13. The device of claim 10, wherein the channels are configured to receive a cooling liquid.

14. A device for dissipating heat generated by computer components, the device comprising:
a base;
a array of fins disposed on a surface of the base, the array of fins including a first group of fins followed by a second group of fins;
a plurality of channels disposed between the first and second group of fins.

15. The device of claim 14, wherein the array of fins include groupings based on size of the fins along a surface of the base.

16. The device of claim 14, wherein the first group of fins comprise a grouping of individual fins, wherein each fins has a width smaller than a width of the second group of fins.

17. The device of claim 14, wherein the second group of fins comprises at least one fin having a width larger than any of the individual fins of the first group of fins.

18. A system for dissipating heat from computer components, the system comprising:
a housing;
at least one water block heat exchanger contained within the housing, the water block heat exchanger comprising:
a base;
a plurality of fins positioned in an array of fins along on a surface of the base; and,
a plurality of channels disposed between the fins.
a coolant reservoir having a coolant pump;
a plurality of conduit to connect the various components of the system and to accommodate the flow of coolant between the pump and the reservoir to the water block heat exchanger.

19. The system of claim 18, wherein the array of fins includes alternating groupings of fins based on a first group of fins having a first size and a second group of fins having a second size.

20. The system of claim 19, wherein the first group of fins are smaller relative to the second group of fins.
